(19) United States
(12) Patent Application Publication
(10) Pub. No.: US 2026/0157084 A1
(43) Pub. Date: Jun. 4, 2026

(54) DISPLAY APPARATUS AND METHOD OF MANUFACTURING THE SAME

(71) Applicant: LG Display Co., Ltd., Seoul (KR)

(72) Inventors: Myung Jae YOO, Paju-si (KR); Jeong Oh KIM, Paju-si (KR); Geum Young LEE, Paju-si (KR); Jae Choul YU, Paju-si (KR); Se Yeon JUNG, Paju-si (KR)

(73) Assignee: LG Display Co., Ltd., Seoul (KR)

(21) Appl. No.: 19/345,253

(22) Filed: Sep. 30, 2025

(30) Foreign Application Priority Data
Dec. 2, 2024 (KR) 10-2024-0176333

(51) Int. Cl. H10K 59/80; H10K 59/12; H10K 59/122; H10K 59/131; H10K 71/16

(52) U.S. Cl. CPC H10K 59/873; H10K 59/1201; H10K 59/122; H10K 59/131; H10K 59/8723; H10K 71/166

(57) ABSTRACT

Disclosed are a display apparatus including a substrate, an active area and a non-active area, a thin-film transistor disposed on the substrate in the active area, a planarization layer having a first contact hole on the thin-film transistor, the planarization layer being disposed in the active area and the non-active area, a bank layer having an open section in an emission layer, the bank layer being disposed on the planarization layer, a light emitting diode disposed on the planarization layer and connected to the thin-film transistor, and a dam disposed in the non-active area, where, in the non-active area between the active area and the dam, the planarization layer includes a plurality of mountain patterns provided parallel to a direction from the active area to the dam and a plurality of first valley patterns provided between the mountain patterns, and a method of manufacturing the same.

### CROSS-REFERENCE TO RELATED APPLICATIONS

This application claims the benefit of and priority to Korean Patent Application No. 10-2024-0176333, filed on Dec. 2, 2024, the entire contents of which are incorporated herein by reference for all purposes as if fully set forth herein.

### BACKGROUND

### 1. Technical Field

The present disclosure relates to a display apparatus, and more particularly to, for example, without limitation, a display apparatus and a method of manufacturing the same which are capable of improving spreadability of a plastic cover layer (PCL) and preventing dents caused by an open metal mask.

### 2. Description of Related Art

An image display apparatus that provides various kinds of information on a screen is core technology in the information and communication era, and is developing in the direction of being thinner, lighter, more portable, and higher-performance. As a result, a display apparatus that may be manufactured in a lightweight and thin form is in the spotlight.

Specific examples of the display apparatus include a liquid crystal display apparatus (LCD), a quantum dot display apparatus (QD), a field emission display apparatus (FED), and an organic light emitting display apparatus (OLED).

The organic light emitting display apparatus includes a light emitting diode including a positive electrode and a negative electrode facing each other in the state in which an organic emission layer is interposed therebetween as an essential component, and displays an image as holes and electrons injected respectively from the positive electrode and the negative electrode are combined with each other in the organic emission layer to emit light.

Therefore, the organic light emitting display apparatus is a self-luminous display apparatus, which is not only advantageous in terms of power consumption due to low voltage operation, but also have excellent color expression, response time, viewing angle, and contrast ratio (CR), and is being studied as a display apparatus.

The organic light emitting display apparatus may include a light emitting diode (LED), a plurality of thin-film transistors and a capacitor configured to drive the light emitting diode, and an encapsulation layer configured to block penetration of external moisture or oxygen into the light emitting diode, which is vulnerable to external moisture or oxygen.

The encapsulation layer includes a plastic cover layer (PCL) made of an organic material. Spreadability of the plastic cover layer must be controlled, but it is difficult to control spreadability of the plastic cover layer, which may cause defects.

In addition, an open metal mask OMM must be used to form the light emitting diode, and the OMM comes into contact with an edge portion, which may easily cause foreign matter to occur, thereby reducing reliability.

The description of related art should not be considered prior art merely because it is mentioned in or associated with this section. The description of related art includes information that describes one or more aspects of the subject technology, and the description in this section does not limit the scope of the invention.

### SUMMARY

Accordingly, one or more aspects of the present disclosure are directed to a display apparatus and a method of manufacturing the same that substantially obviate one or more problems due to limitations and disadvantages of the related art.

It is an aspect of the present disclosure to provide a display apparatus capable of improving spreadability of a plastic cover layer (PCL) and preventing an OMM from contacting an edge portion to prevent dents caused by the OMM and a method of manufacturing the same.

Aspects of the present disclosure devised to solve the problems are not limited to the aforementioned aspect, and other unmentioned aspects will be clearly understood by those skilled in the art based on the following detailed description of the present disclosure.

A display apparatus according to an embodiment of the present disclosure includes a substrate, an active area configured to display an image, a non-active area disposed outside the active area, a thin-film transistor disposed on the substrate in the active area, a planarization layer having a first contact hole on the thin-film transistor, the planarization layer being disposed in the active area and the non-active area, a bank layer having an open section in an emission area, the bank layer being disposed on the planarization layer in the active area and the non-active area, a light emitting diode disposed on the planarization layer and connected to the thin-film transistor via the first contact hole, and a dam disposed at an edge of the non-active area, wherein, in the non-active area between the active area and the dam, the planarization layer includes a plurality of mountain patterns provided parallel to a direction from the active area to the dam and a plurality of first valley patterns provided between the mountain patterns.

A method of manufacturing a display apparatus according to an embodiment of the present disclosure includes preparing a substrate including an active area configured to display an image and a non-active area disposed around the active area, forming a thin-film transistor on the substrate in the active area, forming a voltage supply line on the substrate in the non-active area, forming a planarization layer above the thin-film transistor, the voltage supply line, and a dam area so as to have a first contact hole and a second contact hole on the thin-film transistor and the voltage supply line, forming an anode of a light emitting diode on the planarization layer so as to be connected to the thin-film transistor via the first contact hole and forming a connecting electrode on the planarization layer in the non-active area so as to be connected to the voltage supply line via the second contact hole, forming a bank layer on the planarization layer including the anode, the connecting electrode, and the dam area, the bank layer having an open area provided on the anode and a third contact hole provided on the connecting electrode, forming an emission layer on the anode in the open area using an open metal mask, and forming a cathode on the emission layer and the bank layer so as to be electrically connected to the connecting electrode via the third contact hole, wherein, in the non-active area between the active area and the dam area, the planarization layer includes a plurality of mountain patterns provided parallel to a direction from the active area to the dam and a plurality of first valley patterns provided between the mountain patterns.

Specific details of other embodiments are included in the detailed description and the drawings.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a schematic sectional view of a display apparatus according to an embodiment of the present disclosure;

FIG. 2 is a circuit diagram of a subpixel included in the display apparatus according to the embodiment of the present disclosure;

FIG. 3 is a plan view schematically showing a display panel according to an embodiment of the present disclosure;

FIG. 4 is a sectional view of an arbitrary pixel disposed in an active area of the display panel according to the embodiment of the present disclosure;

FIG. 5 is a sectional view of a non-active area of the display panel according to the embodiment of the present disclosure;

FIG. 6A is a plan view of a second planarization layer of the display panel according to the embodiment of the present disclosure, described with reference to FIG. 5, and FIG. 6B is a sectional view taken along line I-I′ of FIG. 6A;

FIG. 7A is a plan view of a second connecting electrode of the display panel according to the embodiment of the present disclosure, described with reference to FIG. 5, and FIG. 7B is a sectional view taken along line I-I′ of FIG. 7A;

FIG. 8A is a plan view of a spacer of the display panel according to the embodiment of the present disclosure, described with reference to FIG. 5, and FIG. 8B is a sectional view taken along line I-I′ of FIG. 8A;

FIG. 9A is a plan view of a spacer of a display panel according to another embodiment of the present disclosure, described with reference to FIG. 5, FIG. 9B is a sectional view taken along line I-I′ of FIG. 9A, and FIG. 9C is a sectional view taken along line II-II′ of FIG. 9A;

FIGS. 10A to 10E are process sectional views of a display panel in an active area according to an embodiment of the present disclosure; and

FIGS. 11A to 11E are process sectional views of a display panel in a non-active area according to an embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, preferred embodiments of the present disclosure will be described with reference to the accompanying drawings. Throughout the specification, the same reference numerals designate substantially the same components.

In the following description, a detailed description of known technologies and configurations incorporated herein will be omitted when it may make the subject matter of the present disclosure rather unclear. In addition, names of components used in the following description are selected in consideration of ease in preparing the specification, and may be different from names of parts of an actual product.

In the drawings for explaining various embodiments of the present disclosure, for example, the illustrated shape, size, ratio, angle, and number are given by way of example, and thus, are not limitative of the present disclosure. Throughout the specification, the same reference numerals designate the same components.

Also, in describing the specification, a detailed description of known technologies will be omitted when it may make the subject matter of the present disclosure rather unclear.

The terms “comprises”, “includes”, and/or “has”, used in this specification, do not preclude the presence or addition of other elements unless used along with the term “only”. The singular forms are intended to include the plural forms as well, unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In the interpretation of components included in various embodiments of the present disclosure, the components are interpreted as including an error range even if there is no explicit description thereof.

In describing positional relationships in various embodiments of the present disclosure, for example, when the positional relationship between two parts is described using “on”, “above”, “below”, “beside”, or the like, one or more other parts may be located between the two parts unless the term “directly” or “closely” is used therewith.

In describing temporal relationships in various embodiments of the present disclosure, for example, when the temporal relationship between two actions is described using “after”, “subsequently”, “next”, “before”, or the like, the actions may not occur in succession unless the term “immediately” or “directly” is used therewith.

In describing various embodiments of the present disclosure, although terms such as, for example, “first” and “second” may be used to describe various components, these terms are merely used to distinguish the same or similar components from each other. Therefore, in the specification, a component modified by “first” may be the same as a component modified by “second” within the technical scope of the present disclosure unless mentioned otherwise.

The respective features of various embodiments of the present disclosure may be partially or wholly coupled to and combined with each other, and various technical linkages therebetween and operation methods thereof are possible. The various embodiments may be performed independently of each other, or may be performed in association with each other.

Hereinafter, a display apparatus according to an embodiment of the present disclosure will be described with reference to the drawings.

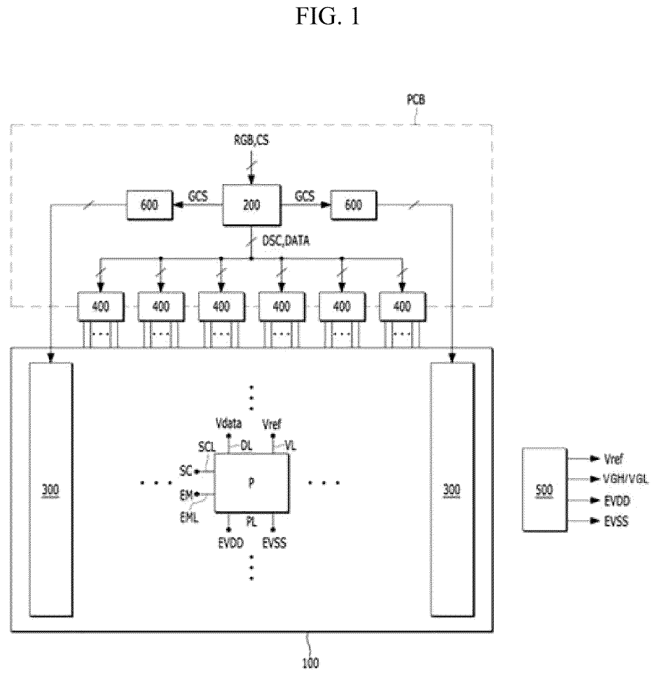

FIG. 1 is a schematic sectional view of a display apparatus according to an embodiment of the present disclosure.

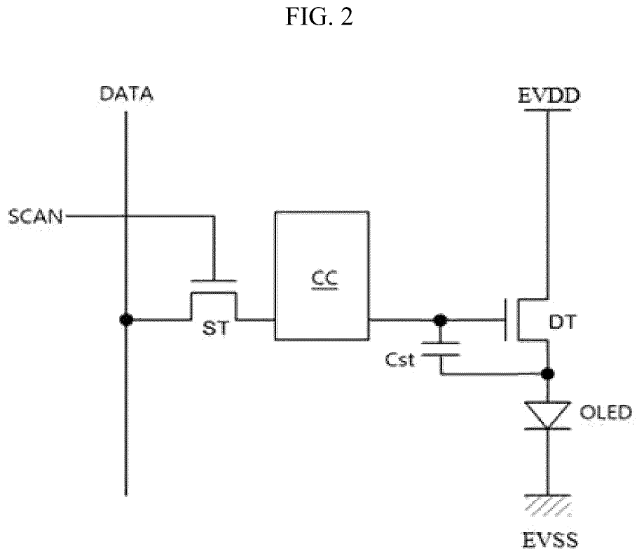

FIG. 2 is a circuit diagram of a subpixel included in the display apparatus according to the embodiment of the present disclosure.

As shown in FIG. 1, the display apparatus according to the embodiment of the present disclosure includes a display panel 100 including a plurality of pixels P, a controller 200, a gate drive circuit 300 configured to supply a gate signal to each of the plurality of pixels P, a data drive circuit 400 configured to supply a data signal to each of the plurality of pixels P, a power supply unit 500 configured to supply power for operation to each of the plurality of pixels P, a level shifter 600 configured to adjust the potential of the gate signal applied to the gate drive circuit 300, and a sensing unit (not shown) configured to sense deterioration of the plurality of pixels P. Here, the controller 200, the gate drive circuit 300, the data drive circuit 400, and the sensing unit may be collectively referred to as a control unit.

The display panel 100 may include an active area in which the pixels P are located and a non-active area in which a gate drive circuit 300 and a data drive circuit 400 are disposed, the non-active area being disposed so as to surround the active area. The gate drive circuit 300 may be disposed in the active area DA.

In the active area of the display panel 100, a plurality of gate lines SCL and EML and a plurality of data lines DL may be disposed so as to intersect each other. Each of the plurality of pixels P is connected to a corresponding one of the gate lines SCL and EML and a corresponding one of the data lines DL. Specifically, one pixel P receives a gate signal from the gate drive circuit 300 via the gate line SCL and EML, receives a data signal from the data drive circuit 400 via the data line DL, and receives a high-potential drive voltage EVDD and a low-potential drive voltage EVSS from the power supply unit 500 via a drive voltage line PL.

Here, the gate lines SCL and EML supply scan signals SC and emission control signals EM, and the data lines DL supply data voltages Vdata. In addition, according to various embodiments, the gate lines SCL and EML may include a plurality of scan lines SCL configured to supply scan signals SC and a plurality of emission control lines EML configured to supply emission control signals EM. In addition, each of the plurality of pixels P may further include a power line VL to receive a reference voltage Vref and an initialization voltage Vini.

Each thin-film transistor (TFT) constituting the pixel P may be implemented as an oxide TFT including an oxide semiconductor layer. The oxide TFT may be advantageous for large-area display panels 100 in consideration of electron mobility, process deviation, etc. The present disclosure is not limited thereto, and the semiconductor layer of the TFT may be made of amorphous silicon or polysilicon.

In addition, each pixel P includes a light emitting diode and a pixel circuit configured to control the operation of the light emitting diode. Here, the light emitting diode may include an anode, a cathode, and an emission layer disposed between the anode and the cathode.

As shown in FIG. 2, each pixel P may include a switching transistor ST, a drive transistor DT, a compensation circuit CC, a light emitting diode OLED, and a storage capacitor Cst.

The light emitting diode OLED may be operated to emit light according to a drive current formed by the drive transistor DT.

The switching transistor ST may be switched such that a data signal DATA supplied through the data line DL is stored in the storage capacitor Cst as a data voltage in response to the scan signal SC supplied through the scan line SCL. The storage capacitor Cst may maintain the data voltage for one frame.

The drive transistor DT may operate such that a constant drive current flows between the high-potential power line EVDD and the low-potential power line EVSS in response to the data voltage stored in the storage capacitor Cst.

The compensation circuit CC is a circuit configured to compensate for the threshold voltage of the drive transistor DT, and the compensation circuit CC may include one or more thin-film transistors and a capacitor. The configuration of the compensation circuit CC may vary greatly depending on a compensation method.

For example, the pixel P shown in FIG. 2 has a 2T (Transistor) 1C (Capacitor) structure including a switching transistor ST, a drive transistor DT, a storage capacitor Cst, and a light emitting diode OLED, but if the compensation circuit CC is added, the pixel may have various structures, such as 3T1C, 4T2C, 5T2C, 6T1C, 6T2C, 7T1C, 7T2C, and 8T1C structures.

The display panel 100 may be implemented as a non-transmissive display panel or a transmissive display panel. The transmissive display panel may be applied to a transparent display apparatus in which an image is displayed on the screen and a real object in the background is visible. The display panel 100 may be manufactured as a flexible display panel. The flexible display panel may be implemented as an organic light emitting display panel using a plastic substrate.

Each pixel P may be divided into a red pixel, a green pixel, and a blue pixel for color realization. Each pixel P may further include a white pixel. Each pixel P includes a pixel circuit.

Touch sensors may be disposed on the display panel 100. Touch input may be sensed using separate touch sensors or through the pixels P. The touch sensors may be implemented as on-cell or add-on type touch sensors that are disposed on the display panel or as in-cell type touch sensors that are embedded in the display panel 100.

The controller 200 processes image data RGB input from the outside so as to correspond to the size and resolution of the display panel 100 and supplies the same to the data drive circuit 400. The controller 200 generates a gate control signal GCS and a data control signal DCS using timing signals CS input from the outside, such as a dot clock signal CLK, a data enable signal DE, a horizontal synchronization signal Hsync, and a vertical synchronization signal Vsync. The generated gate control signal GCS and data control signal DCS are supplied to the gate drive circuit 300 and the data drive circuit 400, respectively, to control the gate drive circuit 300 and the data drive circuit 400.

The controller 200 may be coupled to various processors, such as a microprocessor, a mobile processor, an application processor, depending on a device in which the controller is mounted.

A host system may be any one of a television (TV) system, a set-top box, a navigation system, a personal computer (PC), a home theater system, a mobile device, a wearable device, and a vehicle system.

The controller 200 may control the operation timing of the display panel drive unit using a frame frequency of the input frame frequency×i (where i is a positive integer greater than 0) Hz obtained by multiplying the input frame frequency by i times. The input frame frequency is 60 Hz in a national television standards committee (NTSC) method and 50 Hz in a phase-alternating line (PAL) method.

The controller 200 generates a signal to enable the pixel P to be driven at various refresh rates. That is, the controller 200 generates signals associated with driving such that the pixel P can be driven in a variable refresh rate (VRR) mode or to switch between a first refresh rate and a second refresh rate. For example, the controller 200 may drive the pixel P at various refresh rates by simply changing the speed of a clock signal, generating a synchronizing signal to create a horizontal blank or a vertical blank, or driving the gate drive circuit 300 in a mask manner.

Based on the timing signal CS received from the host system, the controller 200 generates a gate control signal GCS for controlling the operation timing of the gate drive circuit 300 and a data control signal DSC for controlling the operation timing of the data drive circuit 400. The controller 200 controls the operation timing of the display panel drive unit to synchronize the gate drive circuit 300 and the data drive circuit 400.

The data drive circuit 400 receives the image data DATA and the data control signal DCS from the controller 200. The data drive circuit 400 converts the image data DATA into a gamma-compensated voltage to generate a data voltage Vdata in response to the data control signal DCS from the controller 200, and supplies the data voltage Vdata to the data lines DL of the display panel 100 in synchronization with the scan signal SC. The data drive circuit 400 may be connected to the data lines of the display panel 100 through a chip on glass (COG) or tape automated bonding (TAB) process.

The gate drive circuit 300 is operated according to the gate control signal GCS input from the level shifter 600 to generate a gate signal, and sequentially supplies the gate signal to gate lines GL. The gate drive circuit 300 may be formed directly on a lower substrate of the display panel 100 using a gate driver in panel (GIP) method. The gate drive circuit 300 may be formed in the active area DA of the display panel 100 in which the screen is displayed, or may be formed in the non-active area NA outside the active area DA. The non-active area NA may include a bezel area, or may be the same as the bezel area. In the GIP method, the level shifter 600 may be mounted on a printed circuit board (PCB) together with the controller 200.

The power supply unit 500 generates DC power required to drive a pixel array of the display panel 100 and a display panel driver using a DC-DC converter. The DC-DC converter may include a charge pump, a regulator, a buck converter, and a boost converter. The power supply unit 500 receives a DC input voltage from the host system (not shown) to generate DC voltages such as gate-on voltages VGL and VEL, gate-off voltages VGH and VEH, a high-potential drive voltage EVDD, and a low-potential drive voltage EVSS. The gate-on voltages VGL and VEL and the gate-off voltages VGH and VEH are supplied to the level shifter and the gate drive circuit 300. The high-potential drive voltage EVDD and the low-potential drive voltage EVSS are supplied to the pixels P in common.

The level shifter 600 boosts a transistor-transistor-logic (TTL) level voltage of the gate control signal GCS input from the controller 200 to a gate high voltage VGH and a gate low voltage VGL that can drive the TFT formed on the display panel 100 and supplies the same to the gate drive circuit 300. The gate control signal GCS may include a start signal and a clock signal. The plurality of pixels P of the display panel 100 may include at least a first pixel, a second pixel, and a third pixel. The first pixel, the second pixel, and the third pixel may emit light of different colors. For example, the first pixel may be a red pixel, the second pixel may be a green pixel, and the third pixel may be a blue pixel.

The plurality of pixels P may have the same size or different sizes. The first, second, and third pixels may be designed so as to have different sizes taking into account the lifetime of the light emitting diode OLED included in each of the first, second, and third pixels or the color balance.

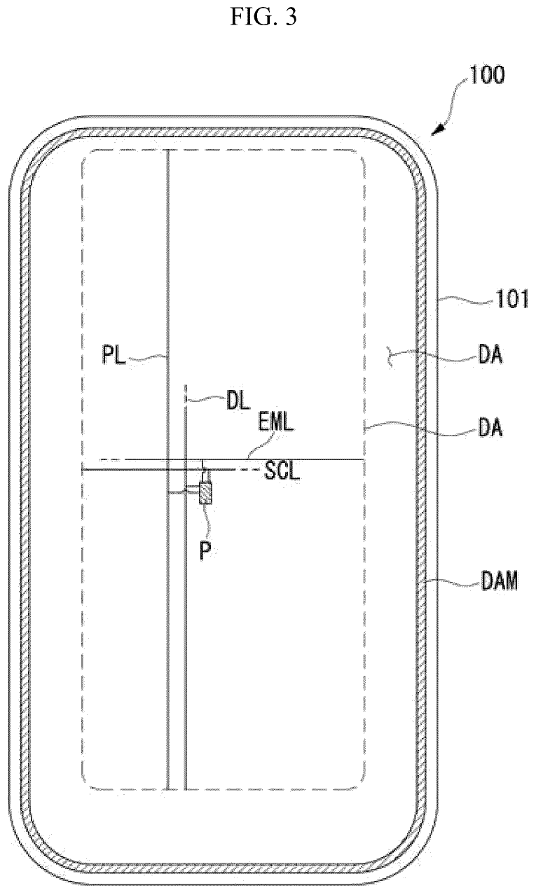

FIG. 3 is a plan view schematically showing a display panel according to an embodiment of the present disclosure.

Referring to FIG. 3, various components constituting the display panel 100 are disposed on a substrate 111. The substrate 111 may include an active area DA for displaying an image and a non-active area NA surrounding the active area DA.

A plurality of pixels P and signal lines configured to apply electrical signals to the pixels P may be disposed in the active area DA. Each pixel P may be implemented as a display element such as an organic light emitting diode OLED. Each pixel P may emit light of red, green, blue, or white. The active area DA is covered with a sealing member so as to be protected from outside air or moisture.

The signal lines that can apply the electrical signals to the pixels P may include a plurality of scan lines SCL configured to supply scan signals SC, a plurality of emission control signal lines EML configured to supply emission control signals EM, a plurality of data lines DL configured to supply a data voltage Vdata, and a plurality of drive voltage lines PL configured to supply a high-potential drive voltage EVDD and a low-potential drive voltage EVSS.

The plurality of scan lines SCL and the plurality of emission control signal lines EML may extend in a first direction (x-axis direction), and the plurality of data lines DL and the plurality of drive voltage lines PL may extend in a second direction (y-axis direction). Each of the plurality of pixels P may be connected to a corresponding one of the plurality of scan lines SCL, a corresponding one of the plurality of data lines DL, and a corresponding one of the plurality of light control signal lines EML.

In the non-active area NA of the display panel 100, a DAM and a power supply line (not shown) configured to supply a common voltage may be disposed.

If a plastic cover layer (PCL) of an encapsulation layer is formed using an inkjet method, the dam DAM may prevent the liquid plastic cover layer (PCL) from spreading to the edge of the substrate 111.

The DAM may be disposed in the non-active area NA. The DAM may be disposed between a second encapsulation layer 122 and a pad area. The DAM may prevent the diffusion of the second encapsulation layer 122 to the pad area, which is disposed at the outermost side of the substrate 111. The DAM may be provided in plural.

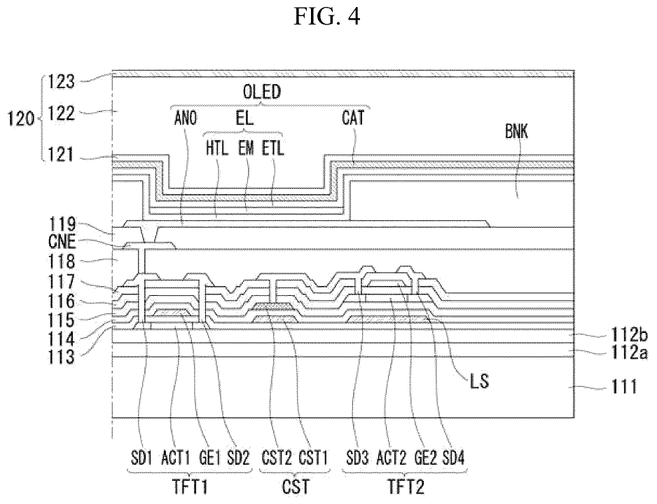

FIG. 4 is a sectional view of an arbitrary pixel disposed in the active area of the display panel according to the embodiment of the present disclosure.

As described above, the plurality of pixels P is disposed in the active area DA. A light emitting diode OLED, transistors TFT1 and TFT2 configured to drive the light emitting diode, a capacitor Cst, and an encapsulation layer 120 may be disposed in the area of each pixel P.

The transistors TFT1 and TFT2 may include a silicon thin-film transistor including a polycrystalline semiconductor material and an oxide thin-film transistor including an oxide semiconductor material. In this case, the thin-film transistor including the polycrystalline semiconductor material may be referred to as a polycrystalline thin-film transistor TFT1, and the thin-film transistor including the oxide semiconductor material may be referred to as an oxide thin-film transistor TFT2. For example, the polycrystalline thin-film transistor TFT1 may be a transistor connected to the light emitting diode OLED, and the oxide thin-film transistor TFT2 may be a transistor connected to the capacitor Cst.

On the other hand, the thin-film transistor including the polycrystalline semiconductor material may be referred to as a polycrystalline thin-film transistor TFT2, and the thin-film transistor including the oxide semiconductor material may be referred to as an oxide thin-film transistor TFT1. For example, the polycrystalline thin-film transistor TFT2 may be a transistor connected to the capacitor Cst, and the oxide thin-film transistor TFT1 may be a transistor connected to the light emitting diode OLED.

Hereinafter, the thin-film transistor including the polycrystalline semiconductor material will be referred to as a polycrystalline thin-film transistor TFT1, and including the thin-film transistors including the oxide semiconductor material will be referred to as an oxide thin-film transistor TFT2.

The substrate 111 may be a flexible substrate. If the substrate 111 is a flexible substrate, the substrate may have a multilayer structure in which organic and inorganic films are alternately stacked. For example, in the substrate 111, an organic film such as polyimide and an inorganic film such as silicon oxide (SiO₂) may be alternately stacked.

A lower buffer layer 112a may be formed on the substrate 111. The lower buffer layer 112a is configured to block moisture that may penetrate from the outside, and may have a structure in which a plurality of silicon oxide (SiO₂) films is stacked. An auxiliary buffer layer 112b configured to protect the element from moisture permeation may be further disposed on the lower buffer layer 112a.

A polycrystalline thin-film transistor TFT1 may be formed on the substrate 111. The polycrystalline thin-film transistor TFT1 may use a polycrystalline semiconductor as an active layer. The polycrystalline thin-film transistor TFT1 may include a first active layer ACT1 including a channel through which electrons or holes move, a first gate electrode GE1, a first source electrode SD1, and a first drain electrode SD2. A first gate insulating layer 113 may be disposed between the first gate electrode GE1 and the first active layer ACT1. The first gate insulating layer 113 may have a single-layer structure or a multilayer structure including an inorganic film, such as a silicon oxide (SiO₂) film or a silicon nitride (SiNₓ) film.

The first active layer ACT1 may include a first channel area, a first source area disposed on one side of the first channel area, and a first drain area disposed on the other side of the first channel area. Each of the first source area and the first drain area is an area in which an intrinsic polycrystalline semiconductor material is doped with group 5 or group 3 dopant ions, such as phosphorus (P) or boron (B), at a predetermined concentration so as to be conductive. The first channel area may maintain the intrinsic state of the polycrystalline semiconductor material, and may provide a movement path for electrons or holes.

According to an embodiment, the polycrystalline thin-film transistor TFT1 may have a top-gate structure in which the first gate electrode GE1 is located on the first active layer ACT1. Accordingly, a first electrode CST1 included in the capacitor Cst and a light shielding layer LS included in the oxide thin-film transistor TFT2 may be made of the same material as the first gate electrode GE1. A mask process may be simplified by forming the first gate electrode GE1, the first electrode CST1, and the light shielding layer LS through a single mask process.

The first gate electrode GE1 may be made of a metal material. For example, the first gate electrode GE1 may have a single-layer structure or a multilayer structure including any one of molybdenum (Mo), aluminum (Al), chromium (Cr), gold (Au), titanium (Ti), nickel (Ni), neodymium (Nd), and copper (Cu) or an alloy thereof; however, the present disclosure is not limited thereto.

A first interlayer insulating layer 114 may be disposed on the first gate electrode GE1. The first interlayer insulating layer 114 may be made of silicon oxide (SiO₂) or silicon nitride (SiNₓ).

Each pixel P of the display panel 100 may further include an upper buffer layer 115, a second gate insulating layer 116, and a second interlayer insulating layer 117 sequentially disposed on the first interlayer insulating layer 114.

The first source electrode SD1 and the first drain electrode SD2 of the polycrystalline thin-film transistor TFT1 may be formed on the second interlayer insulating layer 117. The first source electrode SD1 and the first drain electrode SD2 of the polycrystalline thin-film transistor TFT1 may be connected respectively to the first source area and the first drain area of the first active layer ACT1 through a contact hole formed through the first gate insulating layer 113, the first interlayer insulating layer 114, the upper buffer layer 115, the second gate insulating layer 116, and the second interlayer insulating layer 117.

The upper buffer layer 115 may separate a second active layer ACT2 of the oxide thin-film transistor TFT2 made of the oxide semiconductor material from the first active layer ACT1 made of the polycrystalline semiconductor material, and may provide a base for forming the second active layer ACT2.

The oxide thin-film transistor TFT2 may be formed on the upper buffer layer 115. The oxide thin-film transistor TFT2 may include a second active layer ACT2 made of an oxide semiconductor material, a second gate electrode GE2 disposed on the second gate insulating layer 116, and a second source electrode SD3 and a second drain electrode SD4 disposed on the second interlayer insulating layer 117.

The second active layer ACT2 may be made of an oxide semiconductor material, and may include an intrinsic second channel area that is undoped and a second source area and a second drain area doped so as to be conductive.

The oxide thin-film transistor TFT2 may further include a light shielding layer LS located under the upper buffer layer 115 so as to overlap the second active layer ACT2. The light shielding layer LS may block light incident from the substrate 111 to ensure reliability of the oxide thin-film transistor TFT2. The light shielding layer LS may be made of the same material as the first gate electrode GE1 and may be formed on an upper surface of the first gate insulating layer 113. The light shielding layer LS may be electrically connected to the second gate electrode GE2 to constitute a dual gate.

The second source electrode SD3 and the second drain electrode SD4 may be made of the same material and simultaneously formed on the second interlayer insulating layer 117 together with the first source electrode SD1 and the first drain electrode SD2 to reduce the number of mask processes.

The second gate insulating layer 116 may cover the second active layer ACT2 of the oxide thin-film transistor TFT2. Since the second gate insulating layer 116 is formed on the second active layer ACT2 made of the oxide semiconductor material, the second gate insulating layer may be made of an inorganic film. For example, the second gate insulating layer 116 may be made of silicon oxide (SiO₂) or silicon nitride (SiNₓ).

The second gate electrode GE2 may be made of a metal material. For example, the second gate electrode GE2 may have a single-layer structure or a multilayer structure including any one of molybdenum (Mo), aluminum (Al), chromium (Cr), gold (Au), titanium (Ti), nickel (Ni), neodymium (Nd), and copper (Cu) or an alloy thereof; however, the present disclosure is not limited thereto.

Meanwhile, the first electrode CST1 may be disposed on the first gate insulating layer 113, and a second electrode CST2 may be disposed on the first interlayer insulating layer 114 so as to overlap the first electrode CST1, whereby the capacitor Cst may be implemented. The first electrode CST1 may be made of the same material as the light shielding layer LS and the first gate electrode GE1.

The second electrode CST2 may have a single-layer structure or a multilayer structure including any one of molybdenum (Mo), aluminum (Al), chromium (Cr), gold (Au), titanium (Ti), nickel (Ni), neodymium (Nd), and copper (Cu) or an alloy thereof.

The capacitor Cst may store the data voltage applied through the data line DL for a certain period of time. The capacitor Cst may include two electrodes corresponding to each other and a dielectric disposed therebetween. The first interlayer insulating layer 114 may be located between the first electrode CST1 and the second electrode CST2.

The first electrode CST1 or the second electrode CST2 of the capacitor Cst may be electrically connected to the second source electrode SD3 or the second drain electrode SD4 of the oxide thin-film transistor TFT2. However, the present disclosure is not limited thereto, and the connection relationship of the capacitor Cst may change depending on a subpixel drive circuit.

A first planarization layer 118 and a second planarization layer 119 for surface planarization may be sequentially disposed on the polycrystalline thin-film transistor TFT1, the oxide thin-film transistor TFT2, and the capacitor Cst. Each of the first planarization layer 118 and the second planarization layer 119 may be an organic film such as polyimide or an acrylic resin. The light emitting diode OLED may be formed on the second planarization layer 119.

The light emitting diode OLED may include an anode ANO, a cathode CAT, and an emission layer EL disposed between the anode ANO and the cathode CAT. In the case of implementing a subpixel drive circuit that commonly uses a low-potential power supply voltage connected to the cathode CAT, the anode ANO is disposed as a separate electrode for each subpixel. On the other hand, in the case of implementing a subpixel drive circuit that commonly uses a high-potential power supply voltage, the cathode CAT may be disposed as a separate electrode for each subpixel.

The light emitting diode OLED may be electrically connected to a drive element via an intermediate electrode CNE disposed on the first planarization layer 118. For example, the anode ANO of the light emitting diode OLED and the first source electrode SD1 of the polycrystalline thin-film transistor TFT1 may be connected to each other via the intermediate electrode CNE.

The anode ANO may be connected to the intermediate electrode CNE exposed through a contact hole formed through the second planarization layer 119. The intermediate electrode CNE may be connected to the first source electrode SD1 exposed through a contact hole formed through the first planarization layer 118.

The intermediate electrode CNE may serve as a medium that connects the first source electrode SD1 and the anode ANO. The intermediate electrode CNE may be made of a conductive material such as copper (Cu), silver (Ag), molybdenum (Mo), or titanium (Ti).

The second planarization layer 119 and the intermediate electrode CNE may be omitted. If the second planarization layer 119 and the intermediate electrode CNE are omitted, the anode ANO may be directly electrically connected to the first source electrode SD1 exposed through the contact hole formed through the first planarization layer 118.

The anode ANO may have a multilayer structure including a transparent conductive film and an opaque conductive film with high reflection efficiency. The transparent conductive film may be made of a material with a relatively high work function, such as indium-tin-oxide (ITO) or indium-zinc-oxide (IZO), and the opaque conductive film may have a single-layer or multilayer structure including aluminum (Al), silver (Ag), copper (Cu), lead (Pb), molybdenum (Mo), titanium (Ti), or an alloy thereof. For example, the anode ANO may have a structure in which a transparent conductive film, an opaque conductive film, and a transparent conductive film are sequentially stacked or a structure in which a transparent conductive film and an opaque conductive film are sequentially stacked.

A bank layer BNK may be a subpixel defining layer configured to expose the anode ANO of each subpixel. The bank layer BNK may be made of an opaque material (e.g., black) to prevent optical interference between adjacent subpixels. In this case, the bank layer BNK may include a light shielding material including at least one of color pigment, organic black, and carbon.

In the emission layer EL, hole-related layers including a hole injection layer HIL and a hole transport layer HTL, an organic emission layer including an emission layer EM, and electron-related layers including an electron transport layer ETL and an electron injection layer EIL may be stacked on the anode ANO in the order named or in reverse order. In FIG. 3, only the hole transport layer HTL, the emission layer EM, and the electron transport layer ETL are shown; however, the present disclosure is not limited thereto.

The cathode CAT may be formed on an upper surface and a side surface of the emission layer EL while being opposite the anode ANO with the emission layer EL interposed therebetween. The cathode CAT may be formed integrally so as to cover the entire active area. If the cathode CAT is applied to a front emission type organic light emitting display apparatus, the cathode may be made of a transparent conductive film such as indium-tin-oxide (ITO) or indium-zinc-oxide (IZO).

In addition, an encapsulation layer 120 configured to inhibit the penetration of moisture may be further disposed on the cathode CAT. The encapsulation layer 120 may block the penetration of outside moisture or oxygen into the emission layer EL, which is vulnerable to outside moisture or oxygen. To this end, the encapsulation layer 120 may include at least one inorganic encapsulation layer and at least one organic encapsulation layer; however, the present disclosure is not limited thereto. The encapsulation layer 120 may include a first encapsulation layer 121, a second encapsulation layer 122, and a third encapsulation layer 123, which are sequentially stacked.

Each of the first encapsulation layer 121 and the third encapsulation layer 123 may be made of an inorganic insulating material capable of being low-temperature deposited, such as silicon nitride (SiNₓ), silicon oxide (SiOₓ), silicon oxynitride (SiON), or aluminum oxide (Al₂O₃). Since the first encapsulation layer 121 and the third encapsulation layer 123 are deposited in a low-temperature atmosphere, it is possible to prevent damage to the emission layer EL, which is vulnerable to high temperatures, during a deposition process of the first encapsulation layer 121 and the third encapsulation layer 123.

The second encapsulation layer 122 may serve as a buffer to relieve the stress between the layers due to bending of the display apparatus 10 and may level the step between the layers. The second encapsulation layer 122 may be formed on the substrate 111 on which the first encapsulation layer 121 is formed, and may be made of a non-photosensitive organic insulating material, such as an acrylic resin, an epoxy resin, a phenolic resin, a polyamide resin, a polyimide resin, polyethylene, or silicon oxycarbon (SiOC), or a photosensitive organic insulating material, such as photoreactive acrylic; however, the present disclosure is not limited thereto. The second encapsulation layer 122 may be referred to as a plastic cover layer (PCL).

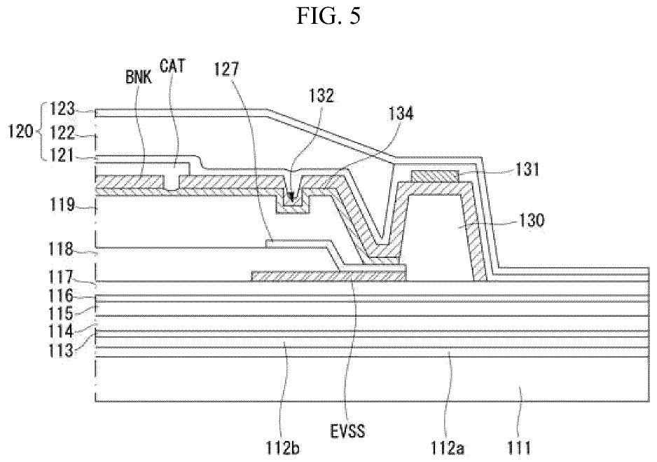

FIG. 5 is a sectional view in the non-active area of the display panel according to the embodiment of the present disclosure.

Since each layer and configuration shown in FIG. 5 is the same as each layer and configuration shown in FIG. 4, the same reference numerals are used, and a description of specific materials will be omitted.

On the substrate 111 in the non-active area, a lower buffer layer 112a and an auxiliary buffer layer 112b may be disposed to block moisture, etc. that may penetrate from the outside.

A first gate insulating layer 113, a first interlayer insulating layer 114, an upper buffer layer 115, a second gate insulating layer 116, and a second interlayer insulating layer 117 are sequentially disposed.

A low-potential drive voltage supply line EVSS configured to supply a low-potential drive voltage EVSS may be disposed on the second interlayer insulation layer 117. The low-potential drive voltage supply line EVSS may be made of the same material and simultaneously formed on the second interlayer insulating layer 117 together with the first source electrode SD1, the first drain electrode SD2, the second source electrode SD3, and the second drain electrode SD4, thereby reducing the number of mask processes.

A first planarization layer 118 for surface planarization may be disposed on the low-potential drive voltage supply line EVSS. The first planarization layer 118 may be patterned to expose the low-potential drive voltage supply line EVSS.

A first connecting electrode 127 may be disposed on the first planarization layer 118 so as to be electrically connected to the low-potential drive voltage supply line EVSS. The first connecting electrode 127 may be made of the same material as the intermediate electrode CNE described with reference to FIG. 4 and simultaneously formed on the first planarization layer 118 together with the intermediate electrode CNE to reduce the number of mask processes.

A second planarization layer 119 for surface planarization may be disposed on the first connecting electrode 127. The second planarization layer 119 may be patterned such that the first connecting electrode 127 is exposed.

A second planarization layer pattern 130 may be formed in the dam DAM area described with reference to FIG. 3. The second planarization layer pattern 130 may be formed over the low-potential drive voltage supply line EVSS and the end of the first connecting electrode 127.

In addition, a valley 132 such as a trench or a groove may be formed in the second planarization layer 119. In addition, various patterns may be further formed in the second planarization layer 119. The specific configuration will be described later.

A second connecting electrode 134 made of the same material as the anode ANO of the light emitting diode OLED described with reference to FIG. 4 may be disposed on the second planarization layer 119. The second connecting electrode 134 may be electrically connected to the low-potential drive voltage supply line EVSS via the first connecting electrode 127. The second connecting electrode 134 may also be patterned in various shapes. The specific configuration thereof will be described later.

A bank layer BNK may be disposed over the second connecting electrode 134 and the second planarization layer pattern 130. A spacer 131 may be disposed on the bank layer BNK. The spacer 131 may also be patterned in various shapes. The specific configuration thereof will be explained later.

Therefore, the dam DAM described with reference to FIG. 3 may be formed by stacking the second planarization layer pattern 130, the bank layer BNK, and the spacer 131.

A contact hole may be formed in the bank layer BNK such that the second connecting electrode 134 is exposed, and the cathode CAT of the light emitting diode OLED may extend to the bank layer BNK in the non-active area. The cathode CAT may be electrically connected to the second connecting electrode 134 via the contact hole of the bank layer BNK.

An encapsulation layer 120 configured to inhibit moisture penetration may be disposed on the cathode CAT and the bank layer BNK. The encapsulation layer 120 may include a first encapsulation layer 121, a second encapsulation layer 122, and a third encapsulation layer 123, which are sequentially stacked.

The first encapsulation layer 121 may extend from the active area to the non-active area. The first encapsulation layer 121 may extend through the dam DAM.

The second encapsulation layer 122 may extend from the active area to the non-active area and may be disposed on the first encapsulation layer 121. The second encapsulation layer 122 may extend inwardly of the dam DAM.

The third encapsulation layer 123 may extend from the active area to the non-active area and may be disposed on the second encapsulation layer 122 and the first encapsulation layer 121. The third encapsulation layer 123 may extend through the dam DAM.

The second planarization layer 119, the second connecting electrode 134, and the spacer 131 may be patterned in various shapes.

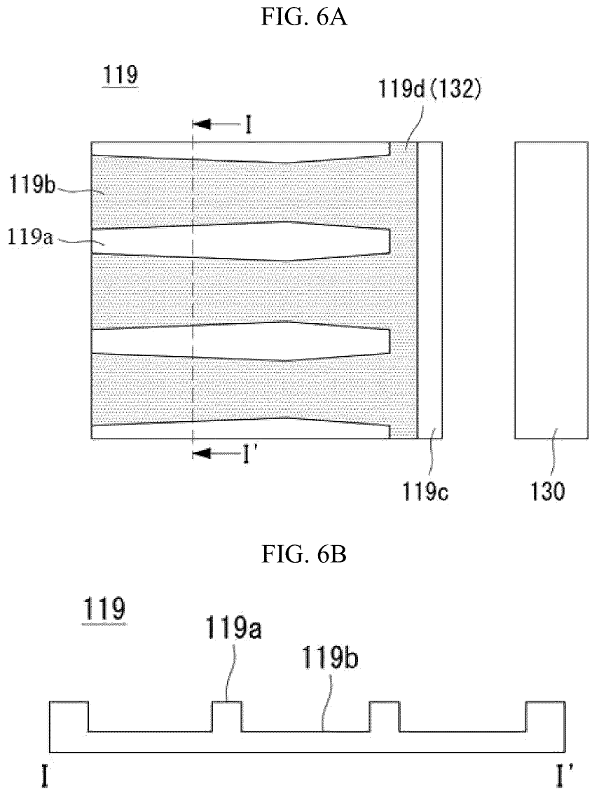

FIG. 6A is a plan view of the second planarization layer 119 of the display panel according to the embodiment of the present disclosure, described with reference to FIG. 5, and FIG. 6B is a sectional view taken along line I-I′ of FIG. 6A. FIGS. 6A and 6B show the second planarization layer 119 disposed in the non-active area.

As shown in FIGS. 6A and 6B, the second planarization layer 119 may have a plurality of mountain patterns 119a, a plurality of first valley patterns 119b, a single bar pattern 119c, and a second valley pattern 119d between the active area DA and the dam DAM. That is, the plurality of mountain patterns 119a is disposed in a direction parallel to the direction from the active area DA to the dam DAM, and the plurality of first valley patterns 119b is formed between the mountain patterns 119a. The bar pattern 119c is formed in a direction perpendicular to the plurality of mountain patterns 119a, and the second valley pattern 119d is formed between the plurality of mountain patterns 119a and the bar pattern 119c.

The plurality of mountain patterns 119a and the bar pattern 119c may be formed through an etching process. That is, a second planarization layer 119 may be formed on the entire surface of the substrate, and parts corresponding to the plurality of first valley patterns 119b and the second valley pattern 119d, excluding the plurality of mountain patterns 119a and the bar patterns 119c, may be etched to a predetermined depth by photolithography. The second planarization layer pattern 130 constituting the dam DAM may also be formed through the etching process.

Each of the plurality of mountain patterns 119a may have a structure in which the width is largest in the center and is gradually reduced toward both ends.

Since the plurality of mountain patterns 119a is formed, as described above, it is possible to easily control spreadability of the second encapsulation layer 122 (plastic cover layer; PCL) described with reference to FIGS. 4 and 5 during a subsequent process of forming the second encapsulation layer 122 (plastic cover layer; PCL).

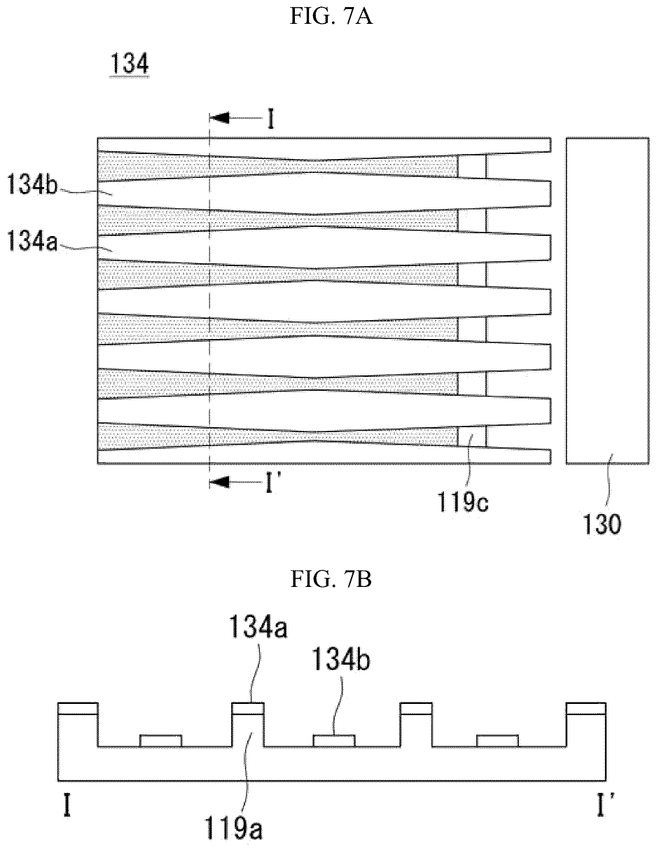

FIG. 7A is a plan view of the second connecting electrode 134 of the display panel according to the embodiment of the present disclosure, described with reference to FIG. 5, and FIG. 7B is a sectional view taken along line I-I′ of FIG. 7A. FIGS. 7A and 7B show the second connecting electrode 134 disposed in the non-active area.

As shown in FIGS. 7A and 7B, the second connecting electrode 134 may include a plurality of first patterns 134a disposed on the plurality of mountain patterns 119a of the second planarization layer 119 and a plurality of second patterns 134b disposed on the plurality of first valley patterns 119b of the second planarization layer 119. The plurality of first patterns 134a and the plurality of second patterns 134b may be disposed so as to be spaced apart from each other. The plurality of first patterns 134a and the plurality of second patterns 134b may extend inwardly of the dam DAM via the bar pattern 119c of the second planarization layer 119 and may be electrically connected to the first connecting electrode 127 described with reference to FIG. 5.

Each of the plurality of first patterns 134a and the plurality of second patterns 134b of the second connecting electrode 134 may have a structure in which the width is largest in the center and is gradually reduced toward both ends.

Since the plurality of first patterns 134a and the plurality of second patterns 134b of the second connecting electrode 134 are formed, as described above, it is possible to easily control spreadability of the second encapsulation layer 122 (plastic cover layer; PCL) described with reference to FIG. 4 during a subsequent process of forming the second encapsulation layer 122 (plastic cover layer; PCL).

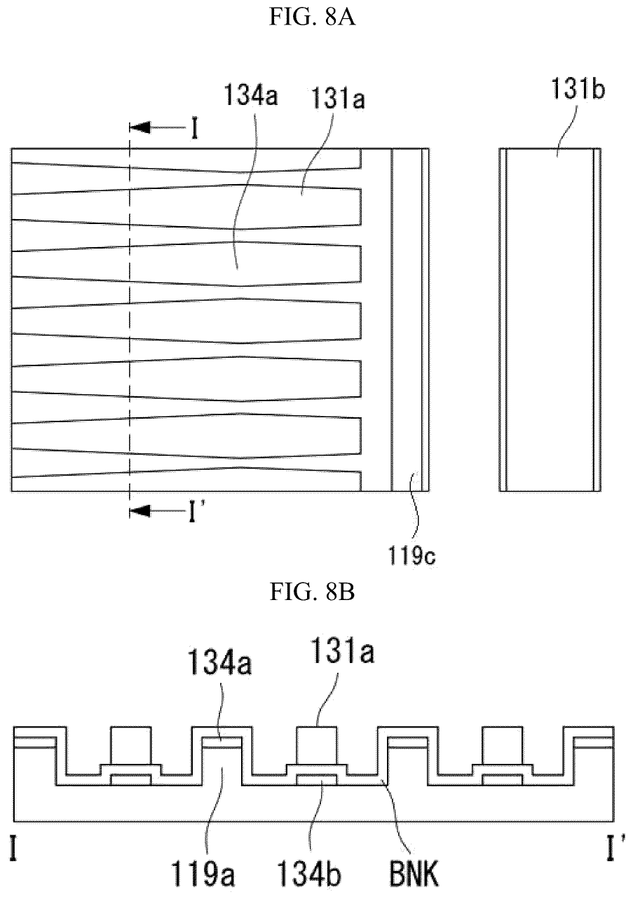

FIG. 8A is a plan view of the spacer 131 of the display panel according to the embodiment of the present disclosure, described with reference to FIG. 5, and FIG. 8B is a sectional view taken along line I-I′ of FIG. 8A. FIGS. 8A and 8B show the spacer 131 disposed in the non-active area.

As shown in FIGS. 8A and 8B, the spacer 131 may include a plurality of first patterns 131a disposed on the plurality of second patterns 134b of the second connecting electrode 134 and a second pattern 131b disposed on the dam DAM.

Each of the plurality of first patterns 131a of the spacer 131 may have a structure in which the width is largest in the center and is gradually reduced toward both ends. Each of the plurality of first patterns 131a of the spacer 131 may be formed so as to have the same width as each of the plurality of second patterns 134b of second connecting electrodes 134.

Since the plurality of first patterns 131a of the spacer 131 is formed, as described above, it is possible to easily control spreadability of the second encapsulation layer 122 (plastic cover layer; PCL) described with reference to FIG. 4 during a subsequent process of forming the second encapsulation layer 122 (plastic cover layer; PCL).

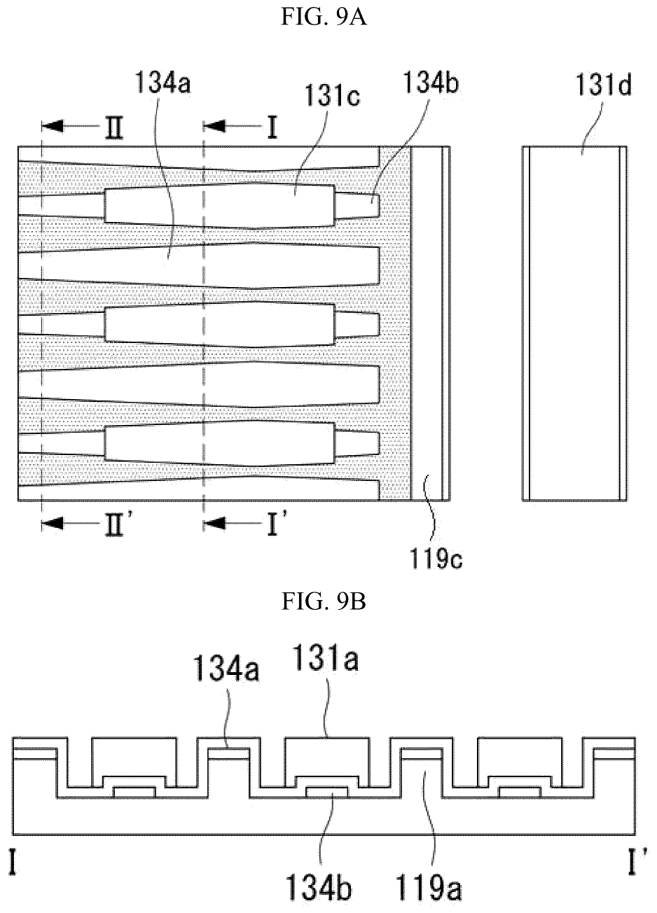

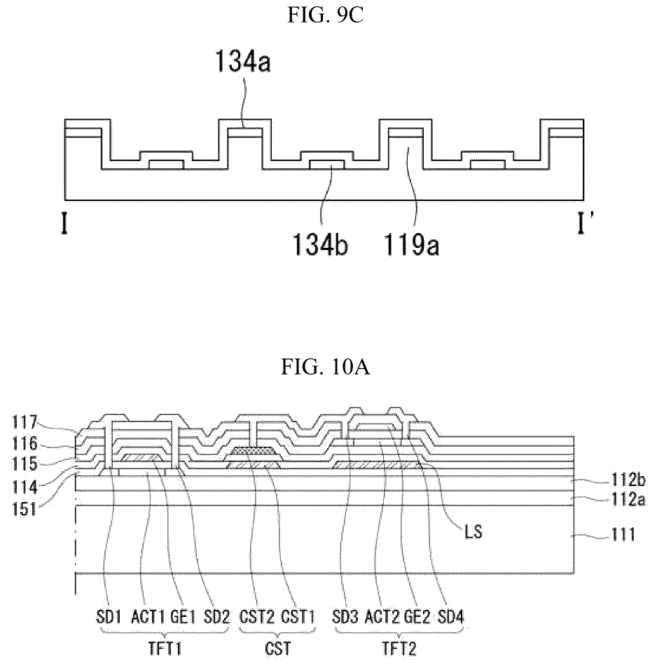

FIG. 9A is a plan view of a spacer 131 of a display panel according to another embodiment of the present disclosure, described with reference to FIG. 5, FIG. 9B is a sectional view taken along line I-I′ of FIG. 9A, and FIG. 9C is a sectional view taken along line II-II′ of FIG. 9A. FIGS. 9A to 9C show the spacer 131 disposed in the non-active area.

As shown in FIGS. 9A to 9C, the spacer 131 may include a plurality of third patterns 131c disposed on the plurality of second patterns 134b of the second connecting electrode 134, and a fourth pattern 131d disposed on the dam DAM.

Each of the plurality of third patterns 131c of the spacer 131 may have a structure in which the width is largest in the center and is gradually reduced toward both ends.

The plurality of first patterns 131a of the spacer 131 described with reference to FIGS. 8A and 8B and the plurality of third patterns 131c of the spacer 131 described with reference to FIGS. 9A and 9B are formed differently from each other. The plurality of first patterns 131a of the spacer 131 and the plurality of third patterns 131c of the spacer 131 may be formed in a similar shape, but the length of the plurality of third patterns 131c of the spacer 131 may be less than the length of the plurality of first patterns 131a of the spacer 131, and the width of the plurality of third patterns 131c of the spacer 131 may be greater than the width of the plurality of first patterns 131a of the spacer 131.

That is, the length of the plurality of first patterns 131a of the spacer 131 is equal to the length of the plurality of mountain patterns 119a of the second planarization layer 119, and the length of the plurality of third patterns 131c of the spacer 131 is less than the length of the plurality of mountain patterns 119a of the second planarization layer 119. In addition, the width of the plurality of first patterns 131a of the spacer 131 may be equal to the width of the plurality of second patterns 134b of the second connecting electrode 134, and the width of the plurality of third patterns 131c of the spacer 131 may be greater than the width of the plurality of second patterns 134b of the second connecting electrode 134.

Since the plurality of first or third patterns 131a or 131c of the spacer 131 is formed, as described above, it is possible to easily control spreadability of the second encapsulation layer 122 (plastic cover layer; PCL) described with reference to FIG. 4 during a subsequent process of forming the second encapsulation layer 122 (plastic cover layer; PCL).

Hereinafter, a method of manufacturing a display apparatus according to an embodiment of the present disclosure will be described.

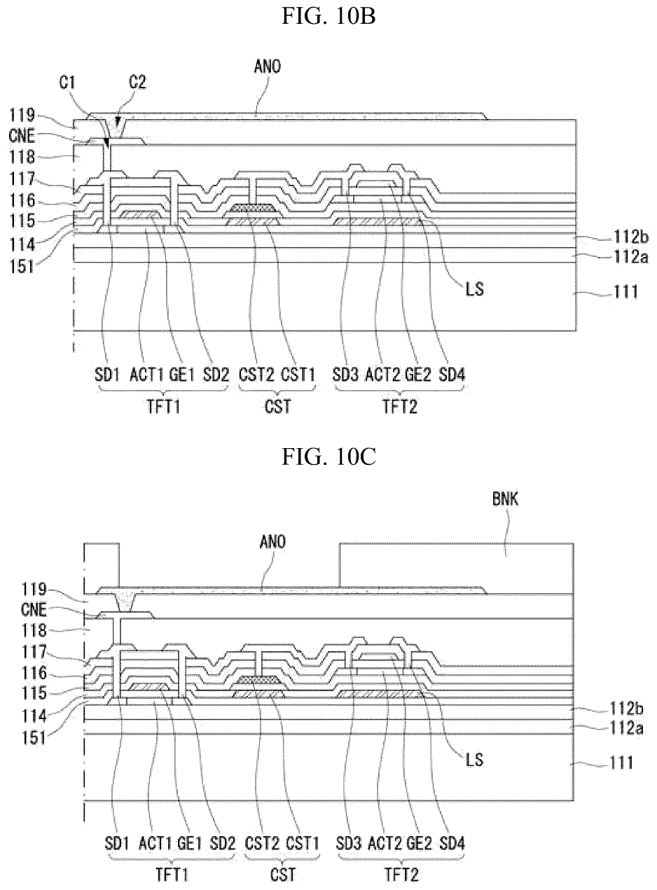

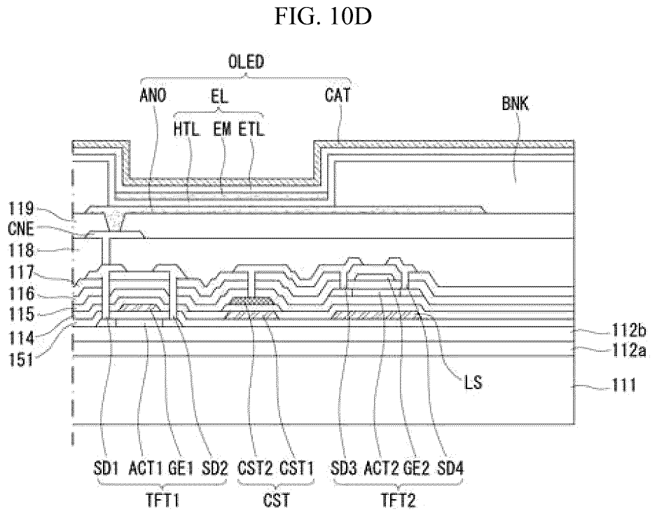

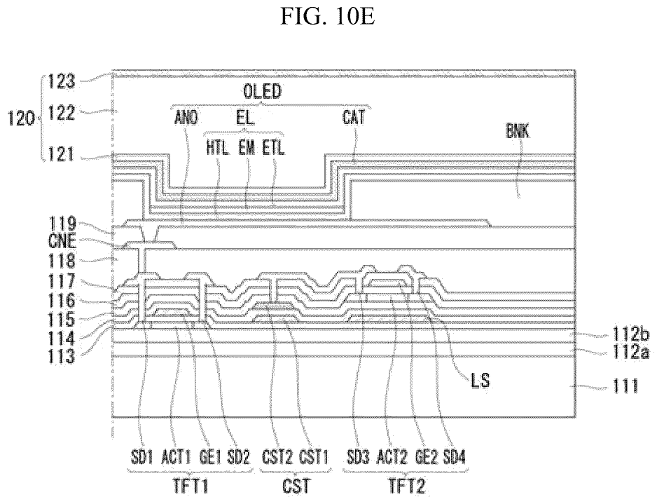

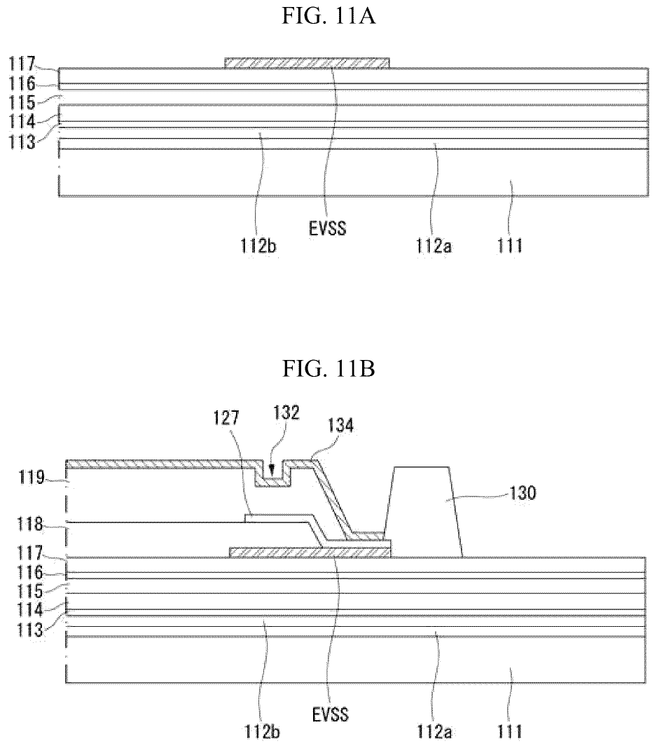

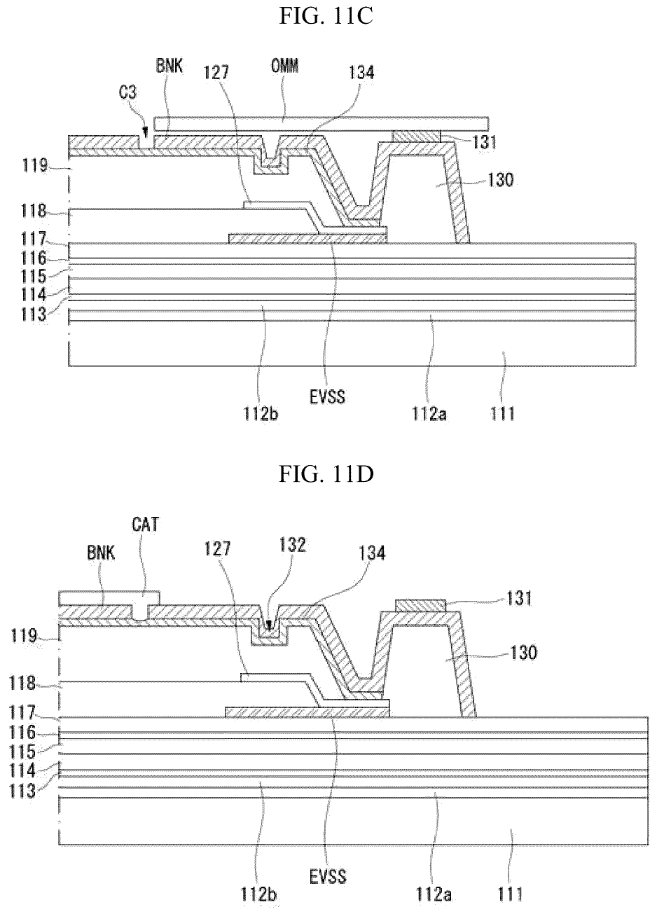

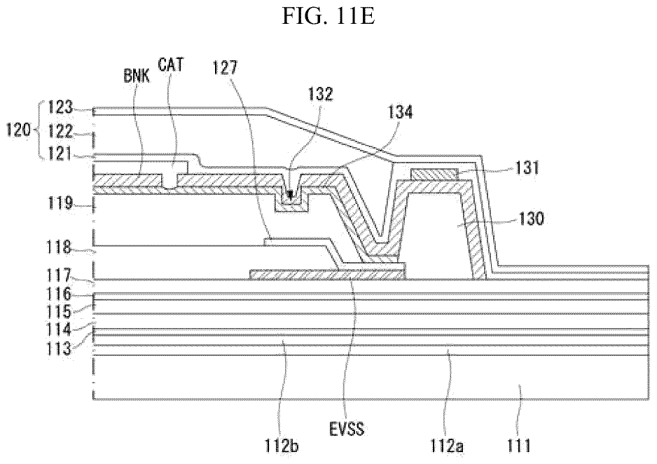

FIGS. 10A to 10E are process sectional views of a display panel in an active area according to an embodiment of the present disclosure. FIGS. 11A to 11E are process sectional views of a display panel in a non-active area according to an embodiment of the present disclosure.

As shown in FIGS. 10A and 11A, a substrate 111 is prepared. The substrate 111 may be a flexible substrate. If the substrate 111 is a flexible substrate, the substrate may have a multilayer structure in which organic and inorganic films are alternately stacked. For example, in the substrate 111, an organic film such as polyimide and an inorganic film such as silicon oxide (SiO₂) may be alternately stacked.

Since the plastic substrate is flexible, the plastic substrate is difficult to use in a process of manufacturing a display panel. Therefore, the plastic substrate is attached to one surface of a carrier substrate such as a glass substrate.

That is, the plastic substrate is formed on the carrier substrate, and a thin-film transistor array layer, a light emitting diode array layer, and an encapsulation layer, which will be described later, are sequentially formed on the plastic substrate. Subsequently, a temporary protective film is attached to the encapsulation layer. Subsequently, the carrier substrate is removed from the plastic substrate, the temporary protective film is removed, and a polarizer and a cover glass are bonded to the encapsulation layer. FIGS. 10A and 11A show the state in which the carrier substrate has been omitted.

A lower buffer layer 112a and an auxiliary buffer layer 112b may be sequentially formed on the substrate 111 over the active area and the non-active area. The lower buffer layer 112a is configured to block moisture that may penetrate from the outside, and may have a structure in which a plurality of silicon oxide (SiO₂) films is stacked. An auxiliary buffer layer 112b configured to protect the element from moisture permeation may be further disposed on the lower buffer layer 112a. At least one of the lower buffer layer 112a and the auxiliary buffer layer 112b may be omitted.

A first thin-film transistor TFT1, a capacitor Cst, and a second thin-film transistor TFT2 may be formed on the substrate 111 in the active area. The first thin-film transistor TFT1 may use a polycrystalline semiconductor as an active layer. The polycrystalline thin-film transistor TFT1 may include a first active layer ACT1 including a channel through which electrons or holes move, a first gate electrode GE1, a first source electrode SD1, and a first drain electrode SD2. A first gate insulating layer 113 may be disposed between the first gate electrode GE1 and the first active layer ACT1. The first gate insulating layer 113 may have a single-layer structure or a multilayer structure including an inorganic film, such as a silicon oxide (SiO₂) film or a silicon nitride (SiNₓ) film.

The first active layer ACT1 may include a first channel area, a first source area disposed on one side of the first channel area, and a first drain area disposed on the other side of the first channel area. Each of the first source area and the first drain area is an area in which an intrinsic polycrystalline semiconductor material is doped with group 5 or group 3 dopant ions, such as phosphorus (P) or boron (B), at a predetermined concentration so as to be conductive. The first channel area may maintain the intrinsic state of the polycrystalline semiconductor material, and may provide a movement path for electrons or holes.

According to an embodiment, the first thin-film transistor TFT1 may have a top-gate structure in which the first gate electrode GE1 is located on the first active layer ACT1. Accordingly, a first electrode CST1 included in the capacitor Cst and a light shielding layer LS included in the second thin-film transistor TFT2 may be made of the same material as the first gate electrode GE1. A mask process may be simplified by forming the first gate electrode GE1, the first electrode CST1, and the light shielding layer LS through a single mask process.

The first gate electrode GE1 may be made of a metal material. For example, the first gate electrode GE1 may have a single-layer structure or a multilayer structure including any one of molybdenum (Mo), aluminum (Al), chromium (Cr), gold (Au), titanium (Ti), nickel (Ni), neodymium (Nd), and copper (Cu) or an alloy thereof; however, the present disclosure is not limited thereto.

A first interlayer insulating layer 114 may be disposed on the first gate electrode GE1. The first interlayer insulating layer 114 may be made of silicon oxide (SiO₂) or silicon nitride (SiNₓ).

An upper buffer layer 115, a second gate insulating layer 116, and a second interlayer insulating layer 117 may be sequentially disposed on the first interlayer insulating layer 114.

The first source electrode SD1 and the first drain electrode SD2 of the first thin-film transistor TFT1 may be formed on the second interlayer insulating layer 117. The first source electrode SD1 and the first drain electrode SD2 of the first thin-film transistor TFT1 may be connected respectively to the first source area and the first drain area of the first active layer ACT1 through a contact hole formed through the first gate insulating layer 113, the first interlayer insulating layer 114, the upper buffer layer 115, the second gate insulating layer 116, and the second interlayer insulating layer 117.

The upper buffer layer 115 may separate a second active layer ACT2 of the second thin-film transistor TFT2 made of an oxide semiconductor material from the first active layer ACT1 made of the polycrystalline semiconductor material, and may provide a base for forming the second active layer ACT2.

The second thin-film transistor TFT2 may be formed on the upper buffer layer 115. The second thin-film transistor TFT2 may include a second active layer ACT2 made of an oxide semiconductor material, a second gate electrode GE2 disposed on the second gate insulating layer 116, and a second source electrode SD3 and a second drain electrode SD4 disposed on the second interlayer insulating layer 117.

The second active layer ACT2 may be made of an oxide semiconductor material, and may include an intrinsic second channel area that is undoped and a second source area and a second drain area doped so as to be conductive.

The second thin-film transistor TFT2 may further include a light shielding layer LS located under the upper buffer layer 115 so as to overlap the second active layer ACT2. The light shielding layer LS may block light incident from the substrate 111 to ensure reliability of the second thin-film transistor TFT2. The light shielding layer LS may be made of the same material as the first gate electrode GE1 and may be formed on an upper surface of the first gate insulating layer 113. The light shielding layer LS may be electrically connected to the second gate electrode GE2 to constitute a dual gate.

The second source electrode SD3 and the second drain electrode SD4 may be made of the same material and simultaneously formed on the second interlayer insulating layer 117 together with the first source electrode SD1 and the first drain electrode SD2 to reduce the number of mask processes.

In addition, a low-potential drive voltage supply line EVSS is formed on the second interlayer insulating layer 117 in the non-active area using the same material as the first source electrode SD1, the first drain electrode SD2, the second source electrode SD3, and the second drain electrode SD4.

The second gate insulating layer 116 may cover the second active layer ACT2 of the second thin-film transistor TFT2. Since the second gate insulating layer 116 is formed on the second active layer ACT2 made of the oxide semiconductor material, the second gate insulating layer may be made of an inorganic film. For example, the second gate insulating layer 116 may be made of silicon oxide (SiO₂) or silicon nitride (SiNₓ).

The second gate electrode GE2 may be made of a metal material. For example, the second gate electrode GE2 may have a single-layer structure or a multilayer structure including any one of molybdenum (Mo), aluminum (Al), chromium (Cr), gold (Au), titanium (Ti), nickel (Ni), neodymium (Nd), and copper (Cu) or an alloy thereof; however, the present disclosure is not limited thereto.

Meanwhile, the first electrode CST1 may be disposed on the first gate insulating layer 113, and a second electrode CST2 may be disposed on the first interlayer insulating layer 114 so as to overlap the first electrode CST1, whereby the capacitor Cst may be implemented. The first electrode CST1 may be made of the same material as the light shielding layer LS and the first gate electrode GE1.

The second electrode CST2 may have a single-layer structure or a multilayer structure including any one of molybdenum (Mo), aluminum (Al), chromium (Cr), gold (Au), titanium (Ti), nickel (Ni), neodymium (Nd), and copper (Cu) or an alloy thereof.

The capacitor Cst may store the data voltage applied through the data line DL for a certain period of time. The capacitor Cst may include two electrodes corresponding to each other and a dielectric disposed therebetween. The first interlayer insulating layer 114 may be located between the first electrode CST1 and the second electrode CST2.

The first electrode CST1 or the second electrode CST2 of the capacitor Cst may be electrically connected to the second source electrode SD3 or the second drain electrode SD4 of the second thin-film transistor TFT2. However, the present disclosure is not limited thereto, and the connection relationship of the capacitor Cst may change depending on a subpixel drive circuit.

The first gate insulating layer 113, the first interlayer insulating layer 114, the upper buffer layer 115, the second gate insulating layer 116, and the second interlayer insulating layer 117 disposed in the active area extend to the substrate 111 in the non-active area, as shown in FIG. 11A.

As shown in FIGS. 10B and 11B, a first planarization layer 118 for surface planarization is formed on the first thin-film transistor TFT1, the second thin-film transistor TFT2, the capacitor Cst, and the low-potential drive voltage supply line EVSS. The first planarization layer 118 is selectively removed to form a first contact hole C1 such that the first source electrode SD1 and the low-potential drive voltage supply line EVSS are exposed.

A conductive material, such as copper (Cu), silver (Ag), molybdenum (Mo), or titanium (Ti), is deposited on the first planarization layer 118 and selectively removed to form an intermediate electrode CNE on the first planarization layer 118 in the active area so as to be electrically connected to the first source electrode SD1 through the first contact hole, and at the same time a first connecting electrode 127 is formed on the first planarization layer 118 in the non-active area so as to be electrically connected to the low-potential drive voltage supply line EVSS through the first contact hole.

A second planarization layer 119 is formed on the first planarization layer 118 including the intermediate electrode CNE and the first connecting electrode 127. A second contact hole C2 is formed in the second planarization layer 119 such that the intermediate electrode CNE and the first connecting electrode 127 are exposed. In addition, a second planarization layer pattern 130 is formed in a dam formation area.

At this time, the second planarization layer 119 is patterned in various shapes, as described with reference to FIGS. 6A and 6B. The various patterns of the second planarization layer 119 have been described with reference to FIGS. 6A and 6B, and therefore a description thereof will be omitted.

Each of the first planarization layer 118 and the second planarization layer 119 may be an organic film such as polyimide or an acrylic resin.

An anode ANO is formed on the second planarization layer 119 in the active area so as to be electrically connected to the intermediate electrode CNE via the second contact hole C2. At the same time, a second connecting electrode 134 is formed on the second planarization layer 119 in the non-active area so as to be electrically connected to the first connecting electrode 127 via the second contact hole. Therefore, the second connecting electrode 134 is electrically connected to the low-potential drive voltage supply line EVSS via the first connecting electrode 127. At this time, the second connecting electrode 134 may also be patterned in various shapes, as described with reference to FIGS. 7A and 7B. The various patterns of the second connecting electrode 134 have been described with reference to FIGS. 7A and 7B, and therefore a description thereof will be omitted.

Each of the anode ANO and the first connecting electrode 127 may have a multilayer structure including a transparent conductive film and an opaque conductive film with high reflection efficiency. The transparent conductive film may be made of a material with a relatively high work function, such as indium-tin-oxide (ITO) or indium-zinc-oxide (IZO), and the opaque conductive film may have a single-layer or multilayer structure including aluminum (Al), silver (Ag), copper (Cu), lead (Pb), molybdenum (Mo), titanium (Ti), or an alloy thereof. For example, the anode ANO may have a structure in which a transparent conductive film, an opaque conductive film, and a transparent conductive film are sequentially stacked or a structure in which a transparent conductive film and an opaque conductive film are sequentially stacked.

As shown in FIGS. 10C and 11C, a bank layer BNK is formed on the second planarization layer 119, on the anode ANO, on the second connecting electrode 134, and on the second planarization layer pattern 130. The bank layer BNK is selectively removed to form an open area on the anode ANO and to form a third contact hole C3 on the second connecting electrode 134.

The bank layer BNK may be a subpixel defining layer configured to expose the anode ANO of each subpixel. The bank layer BNK may be made of an opaque material (e.g., black) to prevent optical interference between adjacent subpixels. In this case, the bank layer BNK may include a light shielding material including at least one of color pigment, organic black, and carbon.

A spacer 131 is formed on the bank layer BNK in the non-active area. That is, a spacer 131 is formed on the bank layer in the dam area, and the spacer 131 may also be patterned in various shapes between the active area and the dam, as described with reference to FIGS. 8A, 8B, 9A, and 9B. The various patterns of the spacer 131 have been described with reference to 8A, 8B, 9A, and 9B, and therefore a description thereof will be omitted.

As described above, the second planarization layer pattern 130, the bank layer BNK, and the spacer 131 are stacked, whereby the dam DAM is completed.

An open metal mask OMM is located above the dam DAM. The height of the dam DAM is greater than the height of the active area DA and greater than the height of the non-active area NA between the dam DAM and the active area DA. Therefore, the open metal mask OMM is not in contact with the surfaces of the active area DA and the non-active area NA. The open metal mask OMM is a mask having an open section in the active area DA. Therefore, it is possible to prevent reduction in reliability due to dents caused by the open metal mask OMM.

As shown in FIGS. 10D and 11D, an emission layer EL is formed on the anode ANO using the open metal mask OMM. In the emission layer EL, hole-related layers including a hole injection layer HIL and a hole transport layer HTL, an organic emission layer including an emission layer EM, and electron-related layers including an electron transport layer ETL and an electron injection layer EIL may be stacked in the order named or in reverse order. In FIG. 10D, only the hole transport layer HTL, the emission layer EM, and the electron transport layer ETL are shown; however, the present disclosure is not limited thereto.

The hole transport layer HTL and the electron transport layer ETL, which are parts of the emission layer EL, may extend to the bank layer BNK in the non-active area.

A cathode CAT is formed on the emission layer EL and the bank layer BNK. The cathode CAT may be formed on an upper surface and a side surface of the emission layer EL while being opposite the anode ANO. The cathode CAT may be formed integrally so as to cover the entire active area. The cathode CAT may be electrically connected to the second connecting electrode 134 in the non-active area via the third contact hole C3 of the bank layer BNK. If the cathode CAT is applied to a front emission type organic light emitting display apparatus, the cathode may be made of a transparent conductive film such as indium-tin-oxide (ITO) or indium-zinc-oxide (IZO).

As shown in FIGS. 10E and 11E, the open metal mask OMM is removed, and an encapsulation layer 120 configured to inhibit the penetration of moisture is formed on the cathode CAT. The encapsulation layer 120 may include a first encapsulation layer 121, a second encapsulation layer 122 and a third encapsulation layer 123, which are sequentially stacked.

The first encapsulation layer 121 may extend from the active area to an upper side of the dam DAM in the non-active area.

The second encapsulation layer 122 may extend from the active area to the non-active area and may be disposed on the first encapsulation layer 121. The second encapsulation layer 122 may extend inwardly of the dam DAM.

The third encapsulation layer 123 may extend from the active area to the non-active area and may be disposed on the second encapsulation layer 122 and the first encapsulation layer 121. The third encapsulation layer 123 may extend upwardly of the dam DAM in the non-active area.

As described above, in the non-active area NA between the active area DA and the dam area, the plurality of mountain patterns 119a is disposed on the planarization layer 119 in the direction parallel to the direction from the active area to the dam, the plurality of first valley patterns 119b is provided between the mountain patterns 119a, and the electrode patterns 134a and 134b and the spacer patterns 131a are selectively formed on the plurality of mountain patterns and the plurality of first valley patterns, whereby it is possible to easily control spreadability of the second encapsulation layer 122 (plastic cover layer) during a subsequent process of forming the second encapsulation layer.

In addition, since the height of the dam DAM is greater than the height of the active area and the height of the non-active area between the dam and the active area, the open metal mask OMM is not in contact with the surfaces of the active area and the non-active area even if the open metal mask OMM is disposed above the dam DAM. Therefore, it is possible to prevent reduction in reliability due to dents caused by the open metal mask OMM.

A display apparatus and a method of manufacturing the display apparatus according to various embodiments of the present disclosure may be described as follows.

A display apparatus according to an embodiment of the present disclosure includes a substrate, an active area configured to display an image, a non-active area disposed outside the active area, a thin-film transistor disposed on the substrate in the active area, a planarization layer having a first contact hole on the thin-film transistor, the planarization layer being disposed in the active area and the non-active area, a bank layer having an open section in an emission layer, the bank layer being disposed on the planarization layer in the active area and the non-active area, a light emitting diode disposed on the planarization layer and connected to the thin-film transistor via the first contact hole, and a dam disposed at an edge of the non-active area, wherein, in the non-active area between the active area and the dam, the planarization layer includes a plurality of mountain patterns provided parallel to a direction from the active area to the dam and a plurality of first valley patterns provided between the mountain patterns.

According to the embodiment of the present disclosure, in the non-active area between the active area and the dam, the planarization layer may further include a bar pattern disposed in a direction perpendicular to the plurality of mountain patterns and a second valley pattern disposed between the plurality of mountain patterns and the bar pattern.

According to the embodiment of the present disclosure, each of the plurality of mountain patterns may be configured such that the width is largest in the center and is gradually reduced toward both ends.

According to the embodiment of the present disclosure, the display apparatus may further include a voltage supply line disposed under the planarization layer in the non-active area, the voltage supply line being configured to supply voltage, and a connecting electrode electrically connected to the voltage supply line, the connecting electrode being disposed on the planarization layer in the non-active area, wherein the connecting electrode may include a plurality of first patterns disposed on the plurality of mountain patterns of the planarization layer and a plurality of second patterns disposed on the plurality of first valley patterns of the planarization layer.

According to the embodiment of the present disclosure, each of the plurality of first patterns and the plurality of second patterns of the connecting electrode may be configured such that the width is largest in the center and is gradually reduced toward both ends.

According to the embodiment of the present disclosure, the display apparatus may further include a plurality of first spacers disposed on the plurality of second patterns of the connecting electrode and a second spacer disposed on the dam.

According to the embodiment of the present disclosure, each of the plurality of first spacers may be configured such that the width is largest in the center and is gradually reduced toward both ends.

According to the embodiment of the present disclosure, each of the plurality of first spacers may have a length equal to the length of each of plurality of mountain patterns of the planarization layer.

According to the embodiment of the present disclosure, each of the plurality of first spacers may have a width equal to the width of each of the plurality of second patterns of the connecting electrode.

According to the embodiment of the present disclosure, each of the plurality of first spacers may have a length less than the length of each of the plurality of mountain patterns of the planarization layer.

According to the embodiment of the present disclosure, each of the plurality of first spacers may have a width greater than the width of each of the plurality of second patterns of the connecting electrode.

A method of manufacturing a display apparatus according to an embodiment of the present disclosure includes preparing a substrate including an active area configured to display an image and a non-active area disposed around the active area, forming a thin-film transistor on the substrate in the active area, forming a voltage supply line on the substrate in the non-active area, forming a planarization layer above the thin-film transistor, the voltage supply line, and a dam area so as to have a first contact hole and a second contact hole on the thin-film transistor and the voltage supply line, forming an anode of a light emitting diode on the planarization layer so as to be connected to the thin-film transistor via the first contact hole and forming a connecting electrode on the planarization layer in the non-active area so as to be connected to the voltage supply line via the second contact hole, forming a bank layer on the planarization layer including the anode, the connecting electrode, and the dam area, the bank layer having an open area provided on the anode and a third contact hole provided on the connecting electrode, forming an emission layer on the anode in the open area using an open metal mask, and forming a cathode on the emission layer and the bank layer so as to be electrically connected to the connecting electrode via the third contact hole, wherein, in the non-active area between the active area and the dam area, the planarization layer includes a plurality of mountain patterns provided parallel to a direction from the active area to the dam and a plurality of first valley patterns provided between the mountain patterns.

As is apparent from the above description, according one or more aspects of the present disclosure, in the non-active area between the active area and the dam area, the non-active area NA between the active area DA and the dam area, the plurality of mountain patterns is disposed on the planarization layer in the direction parallel to the direction from the active area to the dam area, the plurality of first valley patterns is provided between the mountain patterns, and the electrode patterns and the spacer patterns are selectively formed on the plurality of mountain patterns and the plurality of first valley patterns, whereby it is possible to easily control spreadability of the second encapsulation layer (plastic cover layer) during a subsequent process of forming the second encapsulation layer.

In addition, since the height of the dam is greater than the height of the active area and the height of the non-active area between the dam and the active area, the open metal mask OMM is not in contact with the surfaces of the active area and the non-active area even if the open metal mask OMM is disposed above the dam. Therefore, it is possible to prevent reduction in reliability due to dents caused by the open metal mask OMM.

Effects of the present disclosure are not limited by the above mentioned effects, and more various effects are included in this specification.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide non-limiting examples of the technical features of the present disclosure for illustrative purposes. In other words, the disclosed embodiments illustrate the scope of the technical features of the present disclosure and are not intended to be limiting in any respect. Thus, the scope of the present disclosure is not limited to the embodiments shown, but is to be accorded the widest scope consistent with the claims and their equivalents.

What is claimed is:

1. A display apparatus, comprising:
a substrate;
an active area configured to display an image and a non-active area disposed outside the active area;
a thin-film transistor disposed on the substrate in the active area;
a planarization layer having a first contact hole on the thin-film transistor, the planarization layer being disposed in the active area and the non-active area;
a bank layer having an open section in an emission area, the bank layer being disposed on the planarization layer in the active area and the non-active area;
a light emitting diode disposed on the planarization layer and connected to the thin-film transistor via the first contact hole; and
a dam disposed at an edge of the non-active area,
wherein, in the non-active area between the active area and the dam, the planarization layer comprises a plurality of mountain patterns provided parallel to a direction from the active area to the dam and a plurality of first valley patterns provided between the mountain patterns.

2. The display apparatus according to claim 1, wherein, in the non-active area between the active area and the dam, the planarization layer further comprises:
a bar pattern disposed in a direction perpendicular to the plurality of mountain patterns; and
a second valley pattern disposed between the plurality of mountain patterns and the bar pattern.

3. The display apparatus according to claim 1, wherein each of the plurality of mountain patterns is configured such that a width is largest in a center of a corresponding one of the plurality of mountain patterns and is gradually reduced toward both ends of the corresponding one of the plurality of mountain patterns.

4. The display apparatus according to claim 1, further comprising:
a voltage supply line disposed under the planarization layer in the non-active area, the voltage supply line being configured to supply a voltage; and
a connecting electrode electrically connected to the voltage supply line, the connecting electrode being disposed on the planarization layer in the non-active area,
wherein the connecting electrode comprises:
a plurality of first patterns disposed on the plurality of mountain patterns of the planarization layer; and
a plurality of second patterns disposed on the plurality of first valley patterns of the planarization layer.

5. The display apparatus according to claim 4, wherein each of the plurality of first patterns and the plurality of second patterns of the connecting electrode is configured such that a width is largest in a center of a corresponding one of the plurality of first patterns and the plurality of second patterns of the connecting electrode, and is gradually reduced toward both ends of the corresponding one of the plurality of first patterns and the plurality of second patterns of the connecting electrode.

6. The display apparatus according to claim 4, further comprising:
a plurality of first spacers disposed on the plurality of second patterns of the connecting electrode; and
a second spacer disposed on the dam.

7. The display apparatus according to claim 6, wherein each of the plurality of first spacers is configured such that a width is largest in a center of a corresponding one of the plurality of first spacers and is gradually reduced toward both ends of the corresponding one of the plurality of first spacers.

8. The display apparatus according to claim 6, wherein each of the plurality of first spacers has a length equal to a length of a corresponding one of the plurality of mountain patterns of the planarization layer.

9. The display apparatus according to claim 8, wherein each of the plurality of first spacers has a width equal to a width of a corresponding one of the plurality of second patterns of the connecting electrode.

10. The display apparatus according to claim 6, wherein each of the plurality of first spacers has a length less than a length of a corresponding one of the plurality of mountain patterns of the planarization layer.

11. The display apparatus according to claim 10, wherein each of the plurality of first spacers has a width greater than a width of a corresponding one of the plurality of second patterns of the connecting electrode.

12. A method of manufacturing a display apparatus, the method comprising:
preparing a substrate;
forming a thin-film transistor on the substrate in an active area;
forming a voltage supply line on the substrate in a non-active area;
forming a planarization layer above the thin-film transistor, the voltage supply line, and a dam area, wherein the forming of the planarization layer includes having a first contact hole and a second contact hole on the thin-film transistor and the voltage supply line;
forming an anode of a light emitting diode on the planarization layer and forming a connecting electrode on the planarization layer in the non-active area, wherein the forming of the anode includes connecting the anode to the thin-film transistor via the first contact hole, and wherein the forming of the connecting electrode includes connecting the connecting electrode to the voltage supply line via the second contact hole;
forming a bank layer on the planarization layer, on the anode, on the connecting electrode, and in the dam area, the bank layer having an open area provided on the anode and a third contact hole provided on the connecting electrode;
forming an emission layer on the anode in the open area using an open metal mask; and
forming a cathode on the emission layer and the bank layer, wherein the forming of the cathode includes connecting the cathode to the connecting electrode via the third contact hole,
wherein in the non-active area between the active area and the dam area, the planarization layer comprises a plurality of mountain patterns provided parallel to a direction from the active area to the dam area and a plurality of first valley patterns provided between the mountain patterns, and
wherein the display apparatus includes the active area configured to display an image and the non-active area disposed outside the active area.

13. The method according to claim 12, wherein, in the non-active area between the active area and the dam area, the planarization layer further comprises:
a bar pattern disposed in a direction perpendicular to the plurality of mountain patterns; and
a second valley pattern disposed between the plurality of mountain patterns and the bar pattern.

14. The method according to claim 12, wherein each of the plurality of mountain patterns is configured such that a width is largest in a center of a corresponding one of the plurality of mountain patterns and is gradually reduced toward both ends of the corresponding one of the plurality of mountain patterns.

15. The method according to claim 12, wherein the connecting electrode comprises:
a plurality of first patterns disposed on the plurality of mountain patterns of the planarization layer; and
a plurality of second patterns disposed on the plurality of first valley patterns of the planarization layer.

16. The method according to claim 15, wherein each of the plurality of first patterns and the plurality of second patterns of the connecting electrode is configured such that a width is largest in a center of a corresponding one of the plurality of first patterns and the plurality of second patterns of the connecting electrode and is gradually reduced toward both ends of the corresponding one of the plurality of first patterns and the plurality of second patterns of the connecting electrode.

17. The method according to claim 15, further comprising:
forming a plurality of first spacers on the plurality of second patterns of the connecting electrode; and
forming a second spacer in the dam area.

18. The method according to claim 17, wherein each of the plurality of first spacers is configured such that a width is largest in a center of a corresponding one of the plurality of first spacers and is gradually reduced toward both ends of the corresponding one of the plurality of first spacers.

19. The method according to claim 17, wherein each of the plurality of first spacers has a length equal to a length of a corresponding one of the plurality of mountain patterns of the planarization layer, and
wherein each of the plurality of first spacers has a width equal to a width of a corresponding one of the plurality of second patterns of the connecting electrode.

20. The method according to claim 17, wherein each of the plurality of first spacers has a length less than a length of a corresponding one of the plurality of mountain patterns of the planarization layer, and
wherein each of the plurality of first spacers has a width greater than a width of a corresponding one of the plurality of second patterns of the connecting electrode.
